(19) United States
(12) Patent Application Publication
(10) Pub. No.: US 2026/0290441 A1
(43) Pub. Date: Sep. 24, 2026

(54) 3D-DRAM WITH OPEN DIGIT LINE QUILT LAYOUT

(71) Applicant: Micron Technology, Inc., Boise, ID (US)

(72) Inventor: Hiroki Fujisawa, Kanagawa (JP)

(73) Assignee: Micron Technology, Inc., Boise, ID (US)

(21) Appl. No.: 19/556,104

(22) Filed: Mar. 4, 2026

Related U.S. Application Data
(60) Provisional application No. 63/776,516, filed on Mar. 24, 2025.

(51) Int. Cl. G11C 11/4097; G11C 5/06; G11C 11/408; G11C 11/4091

(52) U.S. Cl. CPC G11C 11/4097; G11C 5/063; G11C 11/4085; G11C 11/4087; G11C 11/4091

(57) ABSTRACT

A 3D memory device includes multiple memory patches each of which includes a 3D array of memory cells arranged at the intersection of word lines running in a first direction, local digit lines (LDLs) running in a second direction, and global digit lines (GDLs) running in a third direction. The memory device includes a number of ‘quilts’ each of which includes four memory patches arranged in a 2x2 grid. The sense amplifiers are positioned along the border between patches in the third direction. Adjacent sense amplifiers are couple to adjacent GDLs in the two associated patches. In some embodiments, the sense amplifiers are positioned above the memory patches in the second direction. In some embodiments, multiplexer drivers are also positioned above the array. The quilts may be relatively compact and don’t have sense amplifiers along their edges, allowing for easier tiling at the edge of the device.

### CROSS REFERENCE TO RELATED APPLICATIONS

This application claims the benefit under 35 U.S.C. § 119 of the earlier filing date of U.S. Provisional Application Serial No. 63/776,516 filed Mar. 24, 2025. The aforementioned application is incorporated herein by reference, in its entirety, for any purpose.

### BACKGROUND OF THE INVENTION

Memory devices, such as DRAM devices have generally decreased in size and increased in capacity over time. Many of these gains have been accomplished by miniaturizing circuits such as the sense amplifier, sub-word line driver, and so for forth across different generations of memory devices. However, it is difficult to decrease the size of components below certain size thresholds, which makes it difficult to continue to improve memory device capacity and size in this manner.

It may be possible to increase memory device size and capacity by arranging memory cells in a three dimensional grid instead of a two-dimensional array. For example, multiple memory chips may be stacked on top of each other. However, this increases the thickness of the overall memory device to an extent that may be difficult to accommodate and the number of stacked chips is limited by concerns such as the length of signal lines through the stack, alignment of timing signals, and so forth. Other technologies may be used to generate 3D arrays of memory cells, such as the 3D arrays found in flash memory, but these may have limitations in the speed at which the memory device operates and are generally much slower than the speeds required of a DRAM device. There may be a need for 3D memory devices which operate at high speeds.

### BRIEF DESCRIPTION OF DRAWINGS

FIG. 1 is a block diagram of a 3D memory device according to some embodiments of the present disclosure.

FIG. 2 is a perspective drawing of a single die memory die with an inset showing a ‘top down’ view of two example memory sections according to some example embodiments of the present disclosure.

FIG. 3 is a perspective schematic diagram of a portion of a 3D memory array according to some embodiments of the present disclosure.

FIG. 4 is a perspective view of a memory quilt of a memory device according to some embodiments of the present disclosure.

FIG. 5 is a top-down view of a memory quilt according to some embodiments of the present disclosure.

FIG. 6 is a cross sectional view of a memory device according to some embodiments of the present disclosure.

FIG. 7 is a cross sectional view of a memory device according to some embodiments of the present disclosure.

FIG. 8 is a flow chart of a method of operating a 3D memory array according to some embodiments of the present disclosure.

### DETAILED DESCRIPTION OF THE INVENTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells which store information. For example each memory cell may store a single bit of information as a charge on a capacitive element. In a conventional 2D memory device, the memory cells are logically organized at the intersection of rows and columns. Conductive elements known as word lines couple memory cells along a row, and conductive elements known as digit lines or bit lines couple memory cells along a column. Accordingly, a row address may be used to specify a word line and a column address may be used to specify one or more of the digit lines.

The memory array may be formed of repeating units, referred to as ‘sections’. These sections include one or more patches of the memory array and various circuits which support the operation of that patch. For example, a section may include the patch, sense amplifiers (SA) coupled to the digit lines of that patch, and sub-word line drivers (SWD) coupled to the word lines of the patch. For example, in a conventional 2D memory device, the memory array patch may be generally rectangular with SAs positioned along a ‘top’ and ‘bottom’ edge of the patch and SWDs positioned along a ‘left’ and ‘right’ edge. The top row of sense amplifiers are coupled to either even or odd digit lines (in this and in an adjacent patch), the bottom row of sense amplifiers are coupled to the other digit lines (in this and in an adjacent patch). The SWDs along the edges are similarly coupled to alternate word lines in the patch.

While this layout may be efficient for 2D memory devices, when a third dimension is added, it may become more complicated to generate sections which are compact and which repeat across the memory device. For example, the need for connections to run in a third axis may complicate the placement of components such as SAs and SWDs compared to 2D memory. In addition the expansion into a third dimension may increase the memory cell density enough that it is possible to relax the pitch or spacing between components, which may allow more flexible layouts to be used compared to the layouts which are possible with the stringent pitch requirements of 2D memory. For example, a 3D memory device may have generally greater spacing between components such as word lines, sense amplifiers, and sub-word line drivers compared to a 2D memory. There may be a need for new section layouts in 3D-DRAM devices.

The present disclosure is drawn to apparatuses, systems, and methods for 3D-DRAM with an open digit line quilt layout. An example 3D-DRAM device includes memory cells arranged at the intersection of word lines and local digit lines with the local digit lines coupled together by global digit lines. The word lines, local digit lines, and global digit lines may generally extend in directions which are mutually orthogonal to each other. The present application uses the convention that the word lines generally extend along an ‘x’ direction, the local digit lines generally extend along a ‘z’ direction, and the global digit lines generally extend along a ‘y’ direction. The x, y, and z directions may be orthogonal to each other.

The present disclosure relates to a layout for the sections referred to as a ‘quilt’ which includes four memory patches. The memory patches may be arranged in a 2x2 grid in the x and y directions. The two rows of patches each have a respective SWD region in between. Two sense amplifiers are positioned coupled to the two patches in the two columns. The sense amplifiers in the sense amplifier regions are positioned above the associated memory patches and couple to global digit lines in the two associated patches. Unlike a conventional layout, the sense amplifiers in the region couple to both even and odd digit lines in the associated patches. In this manner, the sense amplifiers are internal to the quilt rather than running along the edge. This may allow for easier tiling of the quilt across the memory device. For example, since global digit lines run to sense amplifiers which are within one quilt, there is no need for different architecture or other changes for quilts positioned on the edge of the memory device which are not adjacent to other quilts on at least one side.

In an example implementation, a quilt includes a first memory patch, a second memory patch, a third memory patch, and a fourth memory patch. A first set of word lines runs between the first and the second memory patch and a second set of word lines runs between the third and the fourth memory patch. A first sense amplifier region includes sense amplifiers coupled to the global digit lines of the first and the third patch and a second sense amplifier region includes sense amplifiers coupled to the global digit lines of the second and the fourth patch. Adjacent sense amplifiers in the regions couple to adjacent global digit lines. So each region includes sense amplifiers coupled to both even and odd global digit lines. The global digit lines are coupled to the sense amplifiers through respective interpatch regions which are positioned between the first and the third patch and the second and the fourth patch.

In some aspects, the present disclosure relates to positioning certain elements related to the section over the array patches. The memory device may be implemented across two dies, a first die which includes the memory array patches, and a second die positioned over that die in the z direction which includes circuits such as the sense amplifiers, sub-word line drivers and multiplexer drivers. The areas which include certain circuits in the second die may be positioned such that they are directly above the memory patches in the second die. For example, when viewed in a ‘top-down’ fashion, in the xy plane, certain circuit regions may overlap the memory patches.

An example implementation may position the sense amplifier regions above the memory patches. Each sense amplifier region includes two portions. For example, the first region includes a first portion and a second portion and the second region includes a third portion and fourth portion. In each region, one of the two portions is positioned over one of the associated patches while the other portion is positioned over the other of the adjacent patches. For example, for the first region, the first portion of sense amplifiers may be positioned above the third patch while the second portion of sense amplifiers may be positioned above the first patch. Similarly, the third portion may be positioned above the fourth patch while the second portion may be positioned above the second patch. In some implementations, multiplexer drivers may also be positioned above the memory patches. For example, each memory patch may have both a sense amplifier portion and a multiplexer driver region positioned above it.

In some aspects, the present application relates to the spatial arrangement of various components. As used herein, when a circuit element is referred to as extending in or along a direction or axis, it refers to a component that is primarily extended in that dimension. However, such an element need not be a perfect line and may have portions which do not exclusively run in the given direction. For example, while a word line may primarily extend along the x axis, it may have portions which extend in the y and/or z directions. As used herein, when a component is referred to as being ‘above’ or ‘below’ another component, it means that at least a portion of the footprint of that component overlaps at least a portion of the footprint of the other component when projected on at least one plane but that they are offset in at least one axis. For example, in some embodiments the sense amplifier region may be above the array patch in the z direction. At least a portion of the xy footprint of the sense amplifier region overlaps at least a portion of the xy footprint of the array patch region, however the sense amplifier region occupies a different range of space long the z coordinate than the array patch region.

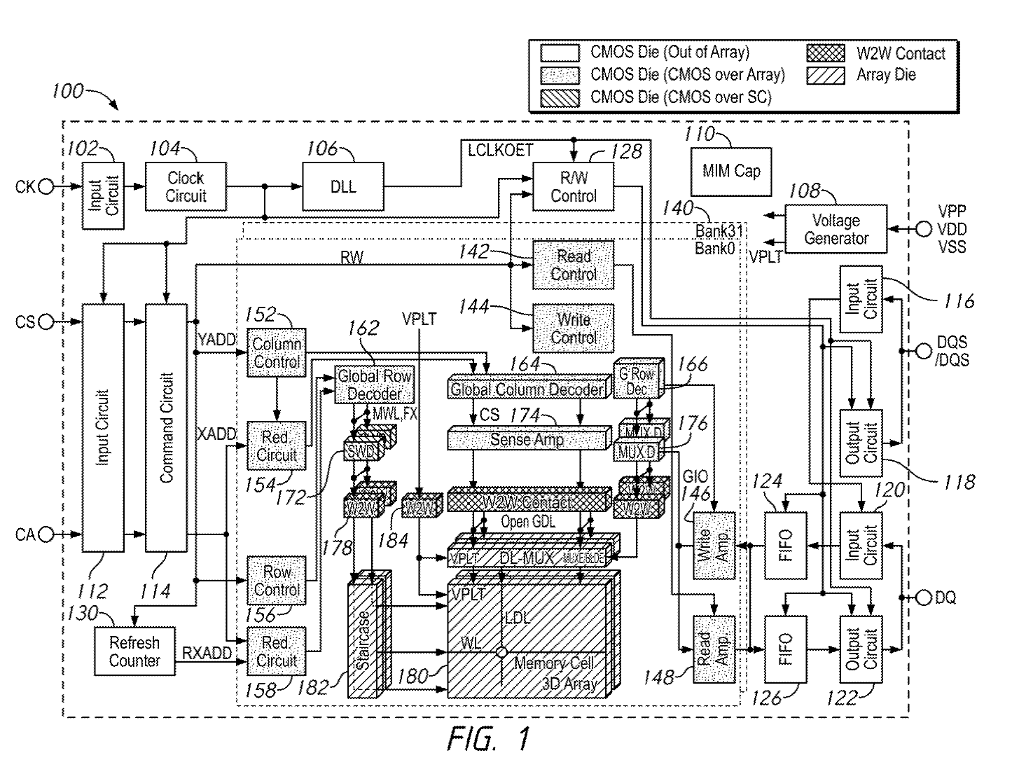

FIG. 1 is a block diagram of a 3D memory device according to some embodiments of the present disclosure. The view of the3D memory device 100 in FIG. 1 is a block diagram representing the different components of the 3D memory device 100. It does not represent the spatial layout of the components of the device, except where otherwise noted.

The 3D memory device 100 may be coupled to a controller (not shown in FIG. 1) which provides various commands, data, and other signals to the memory device 100 to operate the memory. In some embodiments, the 3D memory device 100 may be a stand-alone device. In some embodiments the 3D memory device 100 may be part of a module that packages together several similar memory devices.

The 3D memory device 100 includes a number of external terminals which receive various signals which are used by the device 100. The signals which are received, as well as the signals within the memory device 100, are generally represented by voltages, which different levels of voltage representing different states of the signal. For example, many of the signals used by the memory device 100 may be binary signals, where a first voltage level represents a logical high and a second voltage level represents a logical low. Example terminals include a clock terminal CK, a chip select terminal CS, a command/address terminal CA, data strobe terminals DQS and /DQS, data terminals DQ, and voltage terminals such as VPP, VDD, and VSS. Any of those example terminals may include one or more individual terminals.

The clock signal CK is received by the clock terminal and provided through an input circuit 102 to a clock circuit 104. The clock signal CK is used to control the timing of operations in the memory device 100. The clock circuit 104 generates one or more internal clock signals based on the external clock signal CK and distributes them to various other components of the memory device 100. The clock circuit 104 also provides the clock signal to a delay locked loop (DLL) circuit 106 which generates a delayed clock signal LCLKOET. The delayed clock circuit may be used to match a timing it takes the clock signal to propagate through the memory device 100 and may be used to time read operations. The 3D memory device 100 also receives and provides data strobes DQS and /DQS through a respective input circuit 116 and output circuit 118. During write operations the memory receives a data strobe signal used to time operations of the input circuit 120 for the data DQ. During read operations the memory 100 provides the delayed clock signal LCLKOET to time the operations of a data output circuit 122 to the data terminal DQ. Buffer circuits 124 and 126 are used to serialize or deserialize data between the memory device and the DQ terminals.

The memory device 100 receives voltages at voltage terminals. The voltages are provided to a voltage generator circuit 108 which generates one or more internal voltages based on the provided voltages. The provided voltages as well as the generated voltages are distributed to the various circuits of the memory device 100. For example, the memory device 100 may receive a ground voltage VSS and a system voltage VDD as well as a voltage VPP. The memory includes a MIM capacitor 110 which may be used to help regulate voltages in the device 100.

The memory receives commands and addresses along a command/address bus coupled to CA terminals. The 3D memory device 100 also receives a chip select signal CS, which is used to time signals along the CA terminals, as well as indicate which memory device 100 is receiving commands and addresses in embodiments where multiple memory devices are packaged together. The CS and CA signals are passed through an input circuit 112 to a command/address circuit 114. Examples of addresses include bank address BADD which specifies a bank of the memory device 100, row address XADD which specifies a row of the device, and column address YADD which specifies a column of the device. Examples of commands include activation commands ACT, pre-charge commands PRE, access commands such as read R or write W, or refresh commands. Certain commands and addresses may generally be received together. For example the CA terminal may receive a row activation command ACT along with a row address XADD and bank address BADD. Access commands such as read or write may generally be received along with a column address YADD. A read/write control circuit 128 helps manage the RW commands.

The 3D memory device 100 is divided into one or more memory banks 180. In the embodiment of FIG. 1, there are 32 banks, labelled Bank0 to Bank 31. More or fewer banks may be used in other example embodiments. Each bank is associated with a bank logic region 140, which includes the memory array 180 of the bank as well as various circuits associated with that bank. These circuits may generally be repeated on a bank-by-bank basis. An example bank logic region 140 may include a column control circuit 152 and column redundancy circuit 154, a row control circuit 156 and row redundancy circuit 158, global row decoders 162 and 166, global column decoder 164, sub-word line drivers 172, sense amplifiers 174, multiplexer drivers 176, the array 180 and staircase region 182, digit line multiplexers 184, write amplifiers 146 and read amplifiers 148.

The array 180 is a3D array with memory cells coupled at the intersection of word lines WL and local digit lines LDL. The view of FIG. 1 shows an example slice of the array through an xz plane, showing an example WL and LDL. The LDLs are coupled together along a y axis by global digit lines GDL. The GDLs couple to the sense amplifiers 174. In some embodiments, multiplexers 184 are used to select which LDL(s) are coupled to the respective GDL, and through that GDL to the sense amplifier. A global row decoder 166 is used to selectively activate multiplexer drivers 176 based on the row address, which activate respective ones of the multiplexers 184. In some embodiments, the multiplexers 184 and their respective drivers 176 may not be used and may be eliminated.

The row control circuit 156 activates a word line of the memory array 180 based on the row address. The row control circuit 156 provides internal signals to global row decoder circuits 162 and 166. The global row decoder circuit 162 activates a sub-word line driver 172 associated with the word line specified by XADD. The sub-word line driver 172 is coupled to an associated word line WL through the staircase 182. The sub-word line driver selected by the row address activates the associated word line, causing the memory cells along that word line to couple to the intersecting local digit lines LDLs. The LDLs in turn are coupled along intersecting global digit lines to the sense amplifiers. In some embodiments, the global row decoder circuit 166 activates a multiplexer driver 176 which in turn selects multiplexers 184 to couple the LDLs which intersect the selected word line to the GDLs.

The multiplexers may be an optional component used in some example embodiments. In embodiments where multiplexers are used, the global row decoder circuit 166 receives the row address XADD and uses the row address to determine which multiplexer(s) 176 to activate. Based on the row address the global row decoder circuit 166 provides decoded address to the multiplexer drivers 176, and the multiplexer driver(s) associated with the decoded address provide a multiplexer driver signal. The multiplexers 176 may be grouped together in sets, and the sets are coupled in common to a multiplexer driver 176 provides the multiplexer driver signal, the multiplexers in the set are activated and couple the associated LDL to the GDL. In some embodiments, when the multiplexer driver signal is inactive, the LDL may be decoupled from the GDL and coupled to a ground voltage instead.

The column control circuit 152 selects global digit lines to couple to global input/output lines GIO based on the column address YADD. During a write operation, the GIO lines are coupled to a write amplifier 146, which provides data received from the input circuit 120 through the GIO lines to the selected GDL lines and through those to the memory cells at the intersection of the selected WL and LDL. During a read operation, the data from the memory cells at the intersection of the selected WL and LDL are coupled through the selected GDL to the read amplifier 148, which provides the read data to the output circuit 122.

The memory bank logic region 140 also includes redundancy circuits 154 and 158. The redundancy circuits 154 and 158 are used as part of repair operations. If a row or column address has been repaired, the redundancy circuits 154 or 158 will direct access to a redundant word line or redundant column.

In an example write operation, data received along the DQ terminals is written to specified memory cells of the 3D memory device 100. The device 100 receives a row activation command along with a row address. The global row decoder 162 selects SWDs 172 to activate the associated word line based on the row address. The device 100 receives a write command along with a column address. Data is received by the input circuit 120 and deserialized by a buffer circuit 124 which provides the data to write amplifiers 146. The global column decoder 164 couples selected global digit lines to the GIO lines based on the column address YADD. In some embodiments, a multiplexer driver 176 is activated by the global row decoder 166 and couples a local digit line which intersects the active word line to the respective global digit lines. The data from the write amplifier 146 is written along the GIO lines to GDL line, onto the selected LDL lines and into the memory cells at the intersection of the LDL with the active word line WL.

In an example read operation, data from the array 180 is provided out along the DQ terminals. The device 100 receives a row activation command along with a row address. The global row decoder 162 selects SWDs 172 to activate the associated word line based on the row address. In some embodiments, the global row decoder 166 selects a multiplexer driver 176 to selectively couple one or more selected LDLs to the respective GDL. Data is read out from the memory cells which intersect the active word line through the intersecting LDLs and along the GDLs. The device 100 receives a read command along with a column address. Data is read out from selected ones of the GDLs along the GIO lines to a read amplifier 148. The read amplifier provides the read data to a buffer 126 which serializes the data and provides the serialized data to the output circuit 122.

The 3D memory device 100 may also perform refresh operations. As part of a refresh operation, one or more word lines have the data in the intersecting memory cells refreshed. For example, the memory cells may store information as charge on a capacitive element, and that charge may decay over time. A refresh operation restores that charge to a nominal value. Responsive to a refresh command, a refresh control circuit 130 provides one or more refresh addresses RXADD which specify which word line or word lines should be refreshed.

FIG. 1 generally shows the 3D memory device 100 as a flattened 2D drawing. However certain components may be positioned over other components in an example implementation. For example, the bank logic circuits 140 may be positioned ‘above’ (in the z direction) the memory banks 180. For example, the sub-word line drivers 172 may be positioned above the staircase 182. In some embodiments, the memory device 100 may be printed on two chips, which are then bonded together. For example, components such as the array 180, staircase 182 and digit line multiplexers 184 may be printed in an array die, while the other components are printed on a CMOS die. A set of wafer to wafer (W2W) contacts 178 couple the CMOS die to the array die. In some embodiments, certain components may be positioned above the memory array. For example, at least some of the sense amplifiers 174 may be positioned above the array 180.

The present disclosure will generally be described with respect to an example implementation where two chips are used, however other implementations using more or fewer chips may also be used, and other arrangements of components between chips may be used.

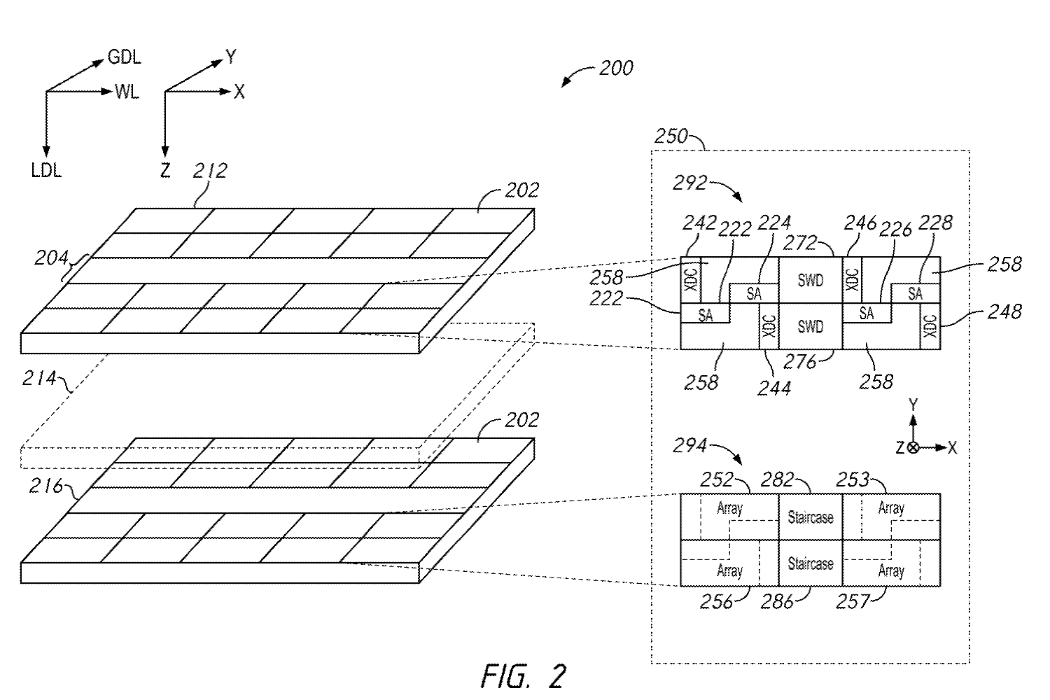

FIG. 2 is a perspective drawing of a single die memory die with an inset showing a ‘top down’ view of two example memory sections according to some example embodiments of the present disclosure. The memory die 200 may, in some embodiments, represent a layout which implements the 3D memory device 100 of FIG. 1.

The memory die 200 includes a number of memory quilts 202, each of which includes one or more sections of memory array, such as memory patches, as well as circuitry which supports the operation of those patches such as SAs (e.g., 174 of FIG. 1) and SWDs (e.g., 172 of FIG. 1). The memory quilts 202 are tiled in the x-y plane of the memory die 200. The memory quilts 202 are sections of the memory array. They may be referred to as quilts herein, because when considered in the xy plane the repeating patterns of circuits tiled across surface of the device are evocative of quilt patches. The memory die 200 also includes a peripheral region 204, which does not have memory quilts 202 tiled across it. The peripheral region 204 may include other circuits which are used in the operation of the memory such as the command circuit 114 of FIG. 1, the input and output circuits 116-122 of FIG. 1 and other components.

The memory device 200 is formed from two die, a first die 212 and a second die 216. The first die 212 is stacked on top of the second die 216 in the z-direction. The first die 212 may be a die which includes various circuits and components which operate the memory device 200, while the second die 216 may be an array die which includes the memory cells, word lines, local digit lines and global digit lines. The second die 216 may also include components which are used to couple components together such as the staircase. The first die 212 may generally be referred to as a CMOS die and the second die 216 may generally be referred to as an array die.

The two die 212 and 216 may be bonded together. For example, wafer-to-wafer (W2W) bonding may be used. A bottom surface in the z direction of the first die 212 may have one or more connection points such as bumps. A top surface in the z direction of the second die 216 may have corresponding connection points such as bumps. When the two die are bonded, the connection points may be electrically coupled between corresponding bumps. In some embodiments, an optional bonding layer 214 between the two die may be used.

In the example of FIG. 2, the peripheral region 204 extends across a width of the two die 212 and 216 in an x-direction, and a portion of the surface of the dice 212 and 216 in the y-direction. The peripheral region 204 is generally centered in the device along the y-axis. The device 200 has memory sections 202 positioned in a grid layout above in the +y direction and below in the -y direction the edges of the peripheral region 204. Other arrangements of the peripheral region 204 and quilts 202 may be used in other example embodiments. FIG. 2 shows a simplified view with a 2x5 grid of quilts 202 on either side of the peripheral region 204. However, more or fewer quilts 202, or different arrangements of quilts 202 may generally be used in other example embodiments. For example, an implementation of a memory device may generally be expected to include many more quilts 202 than the twenty sections illustrated in FIG. 2.

Both die 212 and 216 have memory quilts 202 which have respective portions tiled across the surface of the two die. Each memory quilt 202 has a portion 292 on the first die 212 and a portion 294 on the second die 216. The portions 292/294 of a given memory quilt 202 across the two die are vertically stacked so they align in an x-y plane and are stacked in the z direction.

The inset 250 shows a ‘top down’ view in the xy plane of a quilt 202. The quilt 202 includes four memory array patches 252, 253, 256 and 257. Each memory patch 252-257 includes a 3D array of memory cells at the intersection of word lines and local digit lines, with the local digit lines coupled together by global digit lines. The quilt 202 also includes sense amplifier portions 222-228, sub-word line driver regions 272 and 286, staircase regions 282 and 286, and row decoder/multiplexer driver regions 242-248. The sense amplifier regions 223-236, row decoder/multiplexer drivers 242-248, and SWDs 276 are located in the first die 212 while the staircase regions 286 and array patches 256 and 257 are located in the second die 216.

The portion 292 of the quilt 202 in the first die 212 also includes spacer regions 258, located on either side of the SWD regions 272 and 276. These spacer regions 258 are located above the memory array patches 252-257 in the z direction. The spacer regions 258 may be regions of the first die 212 which are generally empty of circuits in some embodiments.

The example layout of the quilt 202 shown in the inset 250 may be used for each of the quilts 202. The patches 252-257 are generally elongated along the x axis, and are generally longer along the x axis than they are tall along the y axis. Each patch 252-257 is also elongated along the z-axis, which is not shown in the ‘top down’ view of FIG. 2A. The staircase region 282 is positioned between the two array patches 252 and 253 such that the staircase region 282 separates the two patches 252 and 253 along the x axis. The staircase region 282 may be elongated in the x direction and may be longer in the x direction than it is tall in the y direction. In some embodiments, the height of the SWD and staircase region 282 in the y-axis may approximately match the height of the two adjacent array patches 252 and 253. In a similar fashion, the staircase region 286 separates the array patches 256 and 257.

The SWD region 272 is positioned above the staircase region 282. The SWD region 272 may generally have the same x and y dimensions as the staircase region 282. The SWD region 276 is positioned above the staircase region 286 in a similar fashion. Each spacer region 258 is positioned above a corresponding one of the array patches 252-257. Each patch 252-257 has a sense amplifier region and a row decoder/multiplexer driver region positioned above them.

The sense amplifiers are positioned above the patches 252-257. For example, the sense amplifier portion 222 is above the patch 256, the portion 224 is above the patch 252, the portion 226 is above the patch 257 and the portion 228 is above the patch 253. Each of the sense amplifiers is coupled to the respective global digit lines via vertical conductive elements which run in an interpatch region between the two patches. The portions may be offset from each other in a y direction. For example, the portion 222 may be a row of sense amplifiers running from an upper left (e.g., in the +y and -x) corner of the patch 256 to roughly a center of the top (+y) border of the patch 256. The portion 224 is a row of sense amplifiers running from roughly a center of the lower (-y) border of the patch 252 to a lower right (e.g., -y and +x) corner of the patch 252. In other words, considering the interpatch region between patches 252 and 256, the sense amplifier portion 222 is aligned with its top border along the interpatch region while the sense amplifier portion 224 is aligned with its lower border along the interpatch region.

The memory array patches 252-257 represent a piece of the 3D array. For example, each memory patch 252-257 includes memory cells positioned at the intersection of word lines extending along the x axis and local digit lines extending in the z direction, which is into the plane of the page in the view of the inset 250. The local digit lines are coupled together in columns running in the y direction by global digit lines.

The word lines extend between two of the patches. For example, a word line may be continuous across the width of the array patch 252, through the staircase region 282 and across the width of the array patch 253. Another example word line may extend across the patch 256, through the staircase region 286, and through the array patch 257. The word lines intersect memory cells in the array patches, but not in the staircase region when passing underneath the SWDs. For example, a word line intersects local digit lines and memory cells in the array patch 252, then passes through the staircase region 282 without intersecting memory cells or LDLs, and then intersects LDLs and memory cells again in the array patch 253. In other words, when considered along its length in the x direction, each word line has a gap where there are no coupled memory cells in the staircase region.

The SWD regions 272 and 276 include a number of SWDs, each of which is coupled to a respective word line which extends across both of the associated array sections 252/253 or 256/257 through the staircase region 282 and 286. For example, a first SWD in the region 272 is coupled to a first word line which extends across both array patches 252 and 253, a second SWD in the region 272 is coupled to a second word line which extends across both array patches 252 and 253, and so forth. The SWDs in the SWD region 272 or are arranged in a grid, which has dimensions based on the number and arrangement of word lines in the adjacent memory patches 252/253 or 256/257. For example, if there are M word lines in the y-direction and N word lines in the z direction across the two patches 252/253 or 256/257 for a total of NxM word lines in each section 202a1 or 202a2, then there will also be NxM SWDs in the region 272 or 276. For example, the region 272 may have a grid of SWDs with M SWDs in the y-direction and N SWDs in the x direction. Along a given row in the x direction, each SWD couples to a different depth of word line in the z-direction using a connective element which extends along the z-direction to the associated word line.

The global digit lines in the array patches 252-257 are coupled to sense amplifiers in sense amplifier portions 222-228. The global digit lines in the array patches 252 and 256 are coupled to sense amplifier portions 222 and 224, and the global digit lines in the array patches 253 and 257 are coupled to sense amplifier portions 226 and 228. Each sense amplifier is coupled to two global digit lines, one in each of the two associated patches. The sense amplifiers in the first portion 222 are coupled to the first half of the global digit lines in patches 252 and 256, the sense amplifiers in the second portion 224 are coupled to a second half of the global digit lines in patches 252 and 256, the sense amplifiers in the portion 226 are coupled to a first half of the global digit lines in the patches 253 and 257, and the sense amplifiers in the portion 228 are coupled to the second half of the global digit lines in the patches 253 and 257. For example, if there are J global digit lines in each patch, then the portion 222 is coupled to GDL0 to GDL(J/2 – 1) while the portion 224 is coupled to GDL(J/2) to GDL(J-1).

The quilt also includes four row decoder and multiplexer driver regions 242-248. The row decoder and multiplexer driver regions 242-248 include the global row decoder (e.g., 166 of FIG. 1) and the multiplexer drivers (e.g., 176 of FIG. 1). The regions 242-248 are positioned above an associated one of the patches 252-257. Each region 242-248 includes multiplexer drivers which are coupled to multiplexers in the associated patch 252-257. For example, each multiplexer driver may couple to a respective signal line extending in the x direction which couples to a row of multiplexers positioned at the intersection of local digit lines and global digit lines. The regions 242 and 246 are positioned such that a left edge of the regions 242/246 are aligned above a left edge of the associated patches 252/253. Similarly, the regions 244 and 248 are positioned such that a right edge of the regions 244/248 are positioned above a right edge of the associated patches 256/257.

In an example implementation, each of the memory patches 252-257 may include about 8Mbit of storage or about 8,192,000 memory cells. An example memory patch 252 has 8000 word lines arranged in a grid in the yz plane of 80 word lines in the y direction and 100 word lines in the z direction. Each associated sense amplifier region 222 and 224 includes about 512 sense amplifiers coupled to half of the global digit lines which cross the array patch 252, for a total of 1024 global digit lines in the memory patch 252. The SWD region 272 includes 8000 SWDs, one for each word line, arranged in a grid in the xy plane of 80 SWDs in the y direction and 100 in the x direction. The multiplexer regions 242-248 each include 80 multiplexer drivers, each coupled to a signal line coupled to 1024 multiplexers.

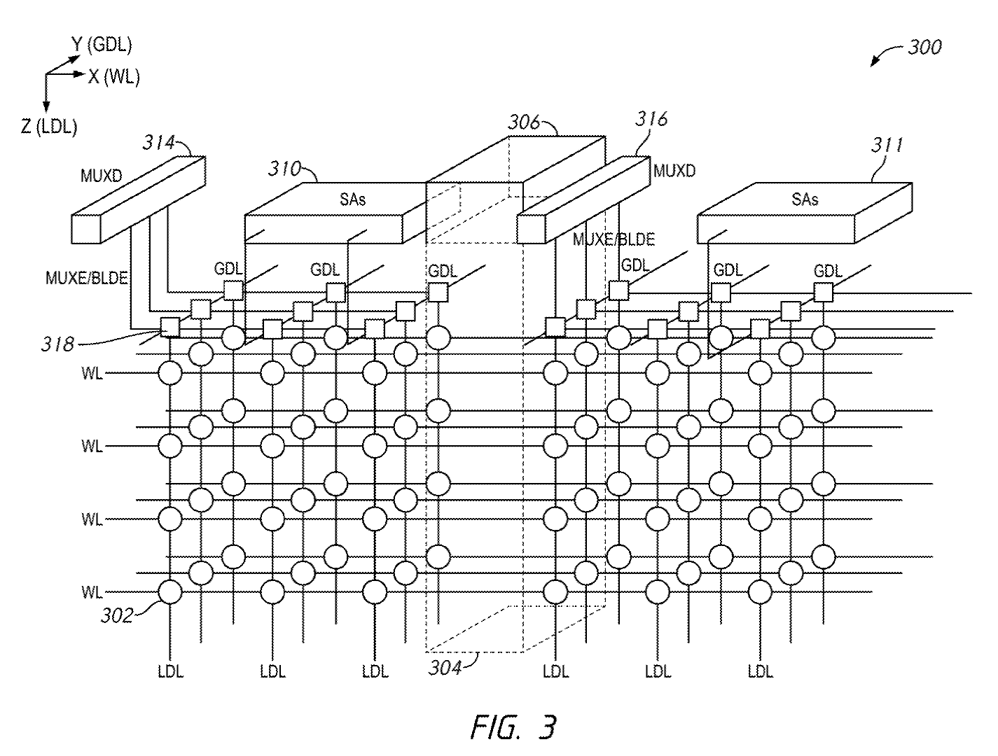

FIG. 3 is a perspective schematic diagram of a portion of a 3D memory array according to some embodiments of the present disclosure. The 3D memory array 300 represents a simplified view of an example portion of a memory array. For example, the 3D memory array 300 may represent a portion of the 3D array 180 of FIG. 1, and/or 252-257 of FIGS. 2. The perspective of FIG. 3 shows an example set of memory cells 302 and their respective word lines, local digit lines and global digit lines.

The memory array 300 shows memory cells 302. Each memory cell 302 is positioned at the intersection of a word line WL and a local digit line LDL. The LDLs are coupled together by global digit lines GDL. The global digit lines are coupled to respective sense amplifiers in sense amplifier portions 310-311 (e.g., 174 of FIG. 1 and/or 222-228 of FIG. 2). The word lines are each coupled to a respective SWD in a SWD region 306 (e.g., 172 of FIG. 1 and/or 272-276 of FIG. 2). The word lines are coupled via a staircase region 304 (e.g., 182 of FIG. 1, 282-286 of FIG. 2) to the SWD region 306. Also shown are multiplexer driver regions 314 and 316 (e.g., 176 of FIG. 1 and/or 242-248 of FIG. 2) which couple to multiplexer circuits 318 (e.g., 184 of FIG. 1).

In some embodiments the SA regions 310-311, multiplexer drivers 314-316 and SWD region 306 may be in a different die than the die which includes the WL, LDL, GDL, memory cells 302 and multiplexer circuits 318. The view of FIG. 3 shows an example embodiment similar to the embodiment of FIG. 2, where the sense amplifier regions 310-311 are positioned above the array patches. In particular, the view of FIG. 3 may represent the patches 252 and 253 of FIG. 2, as well as their associated staircase region 282, sense amplifier regions 224 and 228, SWD regions 272, and multiplexer driver regions 242 and 246.

The staircase region 304 is a 3D region, which may be generally have the form of a rectangular prism. The staircase region 304 is positioned underneath the SWD region 306 in the z-direction. In some embodiments, the staircase region 304 may have the same x-y dimensions as the SWD region 306. The staircase region 304 is positioned between two sections of the word lines WL which intersect memory cells 302. However, the WLs may not intersect any memory cells while they pass through the staircase region 304. Vertical connection elements which extend in the z direction (not shown in FIG. 3) couple each word line to a respective SWD in the SWD region 306. A middle of the word lines WL may be positioned in the staircase region 304.

The word lines WL are arranged in a grid when considered in the yz plane. Similarly, the LDLs may be arranged in a grid when considered in the xy plane. The GDLs are generally arranged in a plane side-by-side with each other.

The LDLs are selectively coupled to the associated GDL through a multiplexer circuit 318. The multiplexers are coupled to multiplexer drivers in a multiplexer driver region 314 or 316. A line of multiplexer drivers may be coupled in common by a multiplexer driver line along the x direction to a multiplexer driver in the multiplexer driver region 314/316. The multiplexer driver provides a multiplexer enable signal MUXE. When MUXE is active, all the multiplexers 318 which are coupled in common to that signal line will couple their respective LDL to the associated GDL.

In some embodiments, the multiplexer drivers 314/316 may also provide a bleed enable signal BLDE. When the bleed enable signal BLDE is active, the multiplexer couples the respective LDL to a ground voltage. In an example operation, the multiplexer driver associated with the row address provides an active MUXE signal and an inactive BLDE signal while the multiplexer drivers which are not associated with the row address provide an active BLDE signal and an inactive MUXE signal. Accordingly, during the operation, multiplexers which receive an active MUXE couple their LDLs to the GDL, while the other multiplexers along each GDL isolate their LDLs from the GDL and instead couple them to a ground voltage so they do not float.

In some embodiments, the decoded row address may be provided multiplexer driver regions, such as 314 and 316, in adjacent memory patches of the same quilt (not shown in FIG. 3). Specifically, the sections share the sense amplifiers 310 and 311. Those multiplexer drivers may also selectively couple LDLs in those sections to the respective GDLs. The sense amplifiers in the regions 308-311 may be coupled to GDLs in those sections. In this way, the capacitance along both GDLs coupled to the SA may match, because the total length of the coupled signal lines may match.

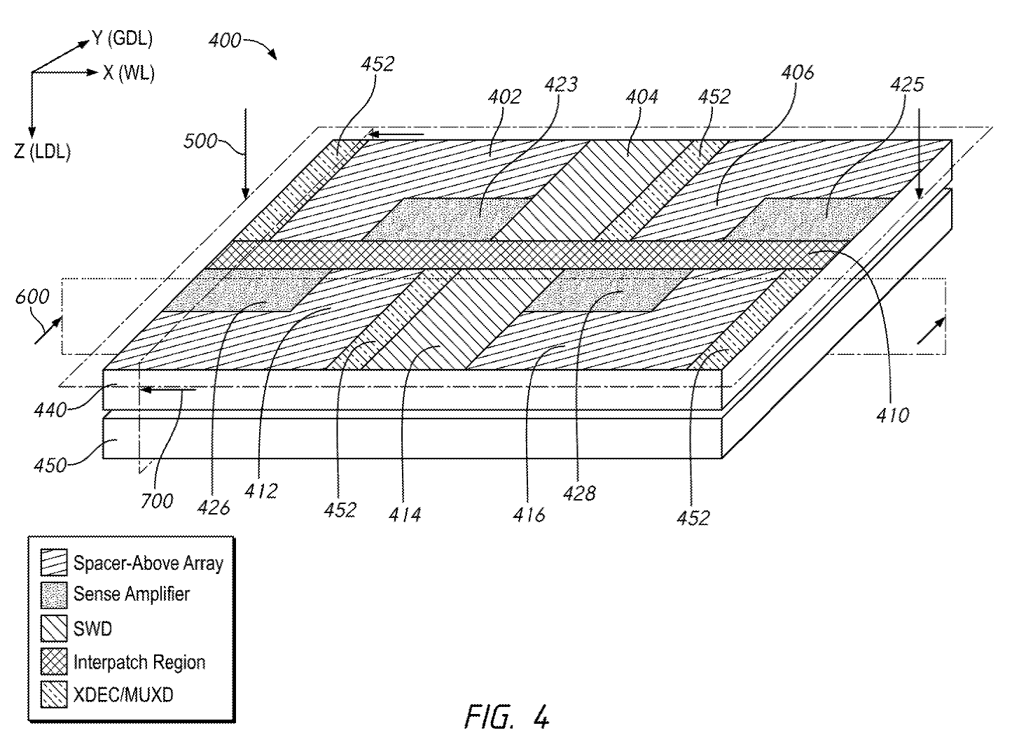

FIG. 4 is a perspective view of a memory quilt of a memory device according to some embodiments of the present disclosure. The memory quilt 400 may represent a portion of a memory device such as 100 of FIG. 1 and/or 200 of FIG. 2. The memory quilt 400 may include one or more memory arrays which have layouts similar to the memory array 300 of FIG. 3 in some embodiments. The memory quilt 400 may be generally similar to the quilt 202 of FIG. 2. However, FIG. 4 shows a perspective view rather than a ‘top down’ view of the xy plane.

The memory device which includes the quilt 400 includes a first die 440 (e.g., 212 of FIG. 2) and a second die 450 (e.g., 216 of FIG. 2). The first die 440 may includes the sense amplifiers, SWDs, and multiplexer drivers. For example the first die 440 may be a CMOS die. The second die 450 includes the memory array patches and staircase regions.

The memory quilt 400 includes a first memory patch 402, a second memory patch 406 and a SWD region 404 in between. The memory quilt 400 also includes a third memory patch 412, a fourth memory patch 416 and a second SWD region 414 in between. An interpatch region 410 is between the patches 402 and 412 and the patches 406 and 416. In the perspective view of FIG. 4, spacer regions are shown on the surface of the first die 440 which are above the memory patches 402-416 in the array die 450 below.

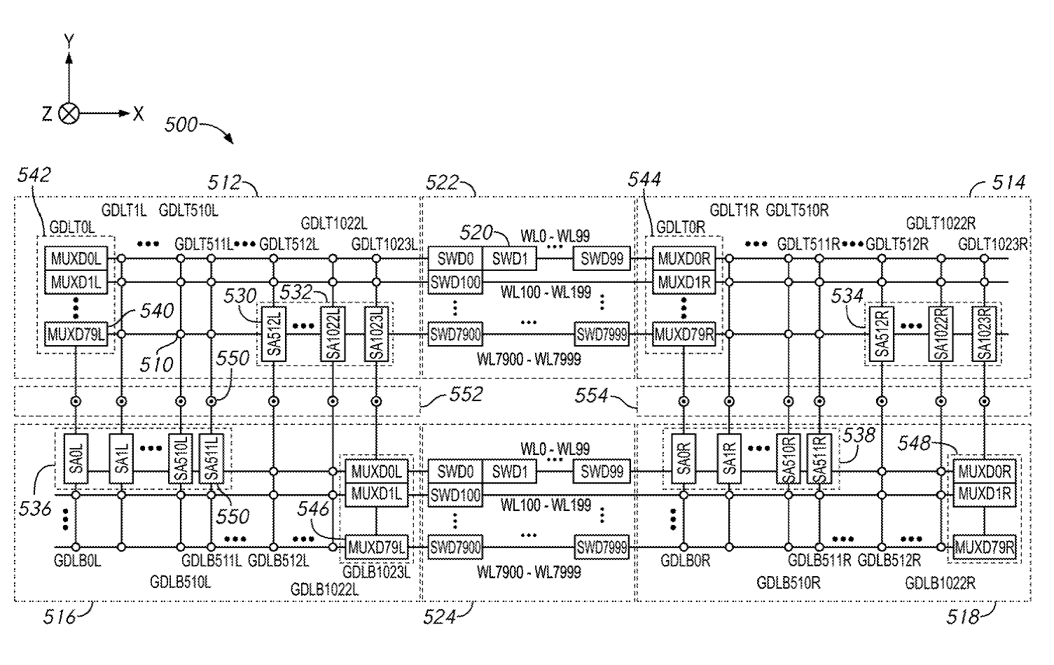

FIG. 4 shows planes 500, 600, and 700 which represent the cross-sectional views of FIGS. 5, 6 and 7, respectively. The plane 500 is a slice along an xy plane of the memory 400 shows the memory patches 402, 406, 412, and 416 (e.g., 252-257 of FIG. 2), the SWD and staircase regions 404 and 414 (e.g., 272/282 and 276/286 of FIG. 2), the multiplexer regions 452, and the sense amplifier regions 423-426 (e.g., 222-228 of FIG. 2). Also shown in the view of the plane 500 is the interpatch region 410.

The plane 600 is a slice along an xz plane of the memory which intersects a second memory patch 412, an SWD and staircase region 414 and a second memory patch 416. The plane 600 also intersects sense amplifier regions 426 and 428 and multiplexer driver regions 452. The plane 700 is a slice along a yz plane which intersects the first memory patch 402, interpatch region 410, and the third memory patch 412. The view 700 also intersects sense amplifier regions 426 and 422 which are above the patches 412 and 402 respectively.

FIGS. 5-7 show different cross-sectional views of the memory device 400 of FIG. 4. Each of FIGS. 5-7 is illustrated with respect to an example embodiment where each memory patch such as 402, 406 or 408 includes 8 Mbit of memory cells. Specifically, they are shown to include a grid of 80 word lines in the y direction and 100 word lines in the z direction, a grid of 80 LDLs in the y direction and 1024 LDLs in the x direction, and 1024 global digit lines side-by-side. This arrangement is shown as an illustrative example only. Other numbers and/or arrangements of word lines, global digit lines, local digit lines, memory cells, sense amplifiers, and so forth may be used in other example embodiments.

FIG. 5 is a top-down view of a memory quilt according to some embodiments of the present disclosure. The quilt 500 shows a view of an example quilt such as 202 of FIG. 2 and/or 400 of FIG. 4. The cross section 500 shows the plane 500 of FIG. 4. The quilt 500 represents a view along an example xy plane, showing a top layer of word lines extending horizontally in an x direction, global digit lines extending in a y direction, and local digit lines extending into the plane of the page in the z direction from the multiplexer circuits 510 where they intersect the GDL. The view of FIG. 5 shows a slice of the ‘top’ word lines in a stack of word lines, with additional word line extending down in layers in the z direction. The ‘top-down’ view of FIG. 5 shows a view of components which are not contained within a single plane. For example, the SWDs 520, sense amplifiers 530, and multiplexer drivers 540 may generally be located in a plane which is above the plane of the word lines, global digit lines, and multiplexers 510 in the z direction. Certain components in the plane of the array, such as certain multiplexers 510, and portions of the global digit lines and word lines may be occluded by the sense amplifiers 530 and multiplexer drivers 540 which are above the memory patch.

The quilt 500 shows four memory patches 512-518 (e.g., 252-257 of FIG. 2 and/or 402-416 of FIG. 4), SWD/staircase regions 522 and 524 (e.g., 172/182 of FIG. 1, 272/282 and 276/286 of FIG. 2 and/or 404 and 414 of FIG. 4), sense amplifier regions 532-538 (e.g., 174 of FIG. 1, 222-228 of FIG. 2, and/or 423-428 of FIG. 4), multiplexer driver regions 542-548 (e.g., 166/176 of FIG. 1, 242-248 of FIG. 2, and/or 452 of FIG. 4), and interpatch regions 552-554 (e.g., 410 of FIG. 4). The array patches 512-418 each include a plurality of memory cells not shown in the view of FIG. 5 at the intersection of word lines and local digit lines. The ‘top’ of the local digit lines are selectively coupled through multiplexers 510 to the associated global digit line. The SWD regions 522-524 include SWD circuits 520. The sense amplifier regions 532-538 include sense amplifier circuits 530. The multiplexer driver regions 542-548 include multiplexer driver circuits 540. The interpatch regions 552 and 554 show the top of vertical conductive elements 550 which couple the global digit lines in the z direction from the xy plane in which they run through the memory patches 512-518 up to the xy plane of the sense amplifiers.

The sense amplifier circuits 530 in the sense amplifier regions 532 and 536 are coupled to global digit lines in the patches 512 and 516. The sense amplifier circuits 530 in the sense amplifier regions 534 and 538 are coupled to global digit lines in the patches 514 and 518. In the sense amplifier regions 534-538, the sense amplifiers are arranged in a row extending in the x direction. A first half of the GDLs (both even and odd) in the patches 512 and 516 are coupled to the sense amplifiers 530 in the portions 536. A second half of the GDLs (both even and odd) in the patches 512 and 516 are coupled to the sense amplifiers 530 in the portion 532. A first half of the GDLs (both even and odd) in the patches 514 and 518 are coupled to the sense amplifiers 530 in the portions 538. A second half of the GDLs (both even and odd) in the patches 514 and 518 are coupled to the sense amplifiers 530 in the portion 534.

In the example of FIG. 5, the halves are organized numerically from a first GDL to the middle GDL, and from the middle GDL to the last GDL when counting across the patches from left to right (or right to left) along the x axis. For example, in the example implementation where there are 1024 GDLs, a first 512 of them from GDL0 to GDL511 are couple to sense amplifiers in the regions 536 and 538, while a second 512 of them from GDL512 to GDL51023 are coupled to sense amplifiers in the regions 532 and 534. Adjacent sense amplifier circuits 530 within a portion 532-538 may generally be coupled to adjacent GDLs. In the example of FIG. 5, each SA region 532-538 includes 512 sense amplifiers, each coupled to two GDLs, one in each of the two associated patches.

The SA portion 532 is located above the patch 512 in the z direction, the SA portion 534 is located above the patch 534 in the z direction, the SA portion 536 is located above the patch 516 in the z direction, and the SA portion 538 is located above the patch 518 in the z direction. The SA portions 532-538 all border an interpatch region 552 or 554. The interpatch regions 552 is between the patches 512 and 516 along the y axis and the interpatch region 554 is between the patches 514 and 518 along the y axis. The SA region 536 is ‘below’ the interpatch region 552 in the y direction, while the SA region 532 is ‘above’ the interpatch region 552 in the y direction. The SA region 538 is ‘below’ the interpatch region 554 in the y direction, while the SA region 534 is ‘above’ the interpatch region 554 in the y direction.

The cross section 500 includes word lines WL0 to WL7999. The word lines are arranged in 80 stacks of 100 word lines each. So the top row of word lines includes the visible word line (WL0) as well as 99 more word lines extending in the z direction into the plane from the point of view of the drawing. Multiplexer circuits 510 couple a ‘top’ of one or more LDLs to associated GDLs. The LDLs are arranged in a grid layout in an xy plane, with a row of the grid including 1024 LDLs along the x direction and a column of the grid including of 80 LDLs along the y direction. The word lines WL extend from the first patch 510 to the second patch 530 under the SWD and staircase region 520.

The SWD and staircase region 522-524 includes a number of SWDs 520. There is a SWD for each word line. In this example there are 8000 SWDs 520, arranged in a grid of 80x100 SWDs in the yz plane. The SWDs 504 are arranged in 80 rows, with each row over a stack of WLs. Since the stacks of WLs are arranged with 100 WLs in each stack, each row of SWDs has 100 SWDs. Each SWD along a row has a conductive element running in the z direction down to the WL it is coupled to. The SWDs along a ‘row’ of the grid of SWDs are coupled to conductive elements of different lengths, since they are coupled to different depths (in the z direction) of word line. When activated by a row activation command, the SWD associated with the row address activates the associated word line.

The LDLs are coupled to the respective GDL by a multiplexer circuit 510. The multiplexer circuit is generally positioned between a ‘top’ of the LDL in the z direction and the GDL. In the embodiment of FIG. 5, there is a multiplexer circuit 510 for each LDL. Other example embodiments may group multiple LDLs together through each multiplexer circuit 510. A multiplexer driver circuit 540 is coupled by one or more signal lines extending in the x direction to a row of multiplexer driver circuits. The signal lines provide multiplexer enable signals, bleed enable signals or both. A row of multiplexers 510 may be coupled to a multiplexer driver in common.

In the embodiment of FIG. 5, the multiplexers 506 are arranged in an xy grid of 80 rows and 1024 columns. Each row of 1024 multiplexers is coupled in common to a multiplexer driver 540 in an associated one of the multiplexer driver regions 542-548. Accordingly, there are 80 multiplexer drivers 540 in each region 542-548. Each region 542-548 is associated with one of the patches 512-518 and is positioned above (in the z direction) the patch it is associated with. So for example the region 542 is above the patch 512, the region 544 is above the patch 514, the region 546 is above the patch 516 and the region 548 is above the patch 518.

The multiplexer regions 542-548 each include multiplexer drivers 540 arranged in a column extending in y direction. Each multiplexer driver 540 may be associated with a row of multiplexers 510 extending in the x direction in the associated patch 512-518. In other words, each multiplexer driver 540 may be associated with a ‘stack’ of word lines and specifically the portion of that word line on one side of the SWD region 522/524. So, for example a first multiplexer driver MUXD0L may be associated with the portions of WL0-WL99 to the left of SWD region 522, a second multiplexer driver MUXD1L may be associated with the portions of WL100-WL199 to the left of SWD region 522 and so forth.

The multiplexer driver regions 542-548 are positioned along an edge of the patch opposite the corner that the sense amplifier region 532-538 is positioned along. For example, making reference to the layout of the FIG. 5, in the patches 512 and 514, the sense amplifier region 532 and 534 are positioned above a lower right corner of the respective patches 512 and 515, and the multiplexer driver regions 542 and 544 are positioned along a left edge of the patches 512 and 514. The layout of the patches 516 and 518 reverse this, with the sense amplifier regions 536 and 538 positioned above an upper left corner of the patches 536 and 538 and the multiplexer driver regions 546 and 548 positioned above a right edge of the patches 516 and 518. Another way of considering the placement of the multiplexer driver regions 542-548 is that the regions 546 and 544 are positioned along edges of the patch proximal to the associated SWD regions 522/524, while the regions 542 and 548 are positioned along edges of the patch distal from the associated SWD regions 522/524.

In an example operation, when a row activation command is received along with a row address, the SWD 520 associated with that address activates the associated word line. The associated multiplexer driver 562 activates the multiplexer circuit 506 so that the LDLs which intersect the active word line are coupled to the respective GDLs. When the word line is activated, the memory cells along that word line are coupled to the intersecting LDL 506, and change a voltage of the LDL and the GDL that LDL is coupled to based on the stored charge. The SA coupled to that GDL senses this change and amplifies it during a read operation, or drives a new value onto the GDL in a write operation.

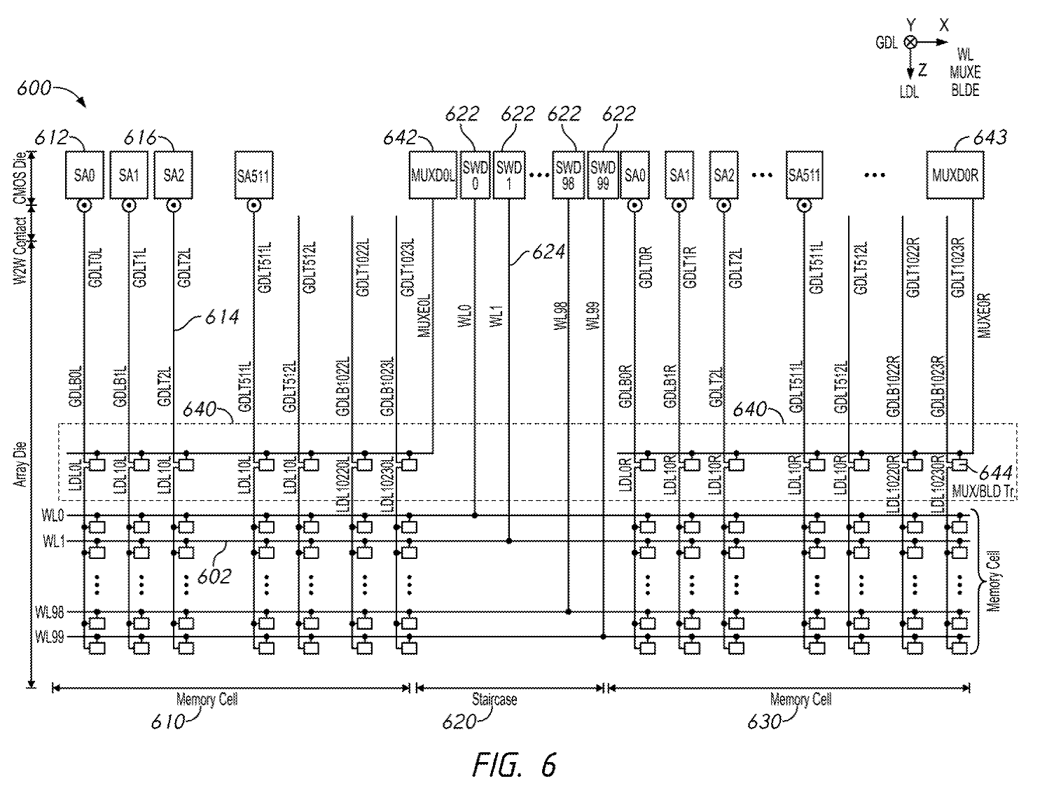

FIG. 6 is a cross sectional view of a memory device according to some embodiments of the present disclosure. The cross section 600 shows the plane 600 of FIG. 4. The cross section 600 represents a view along an example xz plane, showing word lines running horizontally along the x direction, local digit lines running vertically along a z direction, and global digit lines running into and out of the plane of the page along a y direction. A vertical conductive element 614 is shown in an interpatch region (e.g., 410 of FIG. 4) which runs ‘behind’ the plane of the cross section 600. The vertical conductive element 614 is coupled to a horizontal element 616 which couples to the sense amplifiers 612, which are positioned over the memory cells. The sense amplifiers 612 shown are in the sense amplifier portions which are positioned over a left half of the GDLs (e.g., portions 222 and 226 of FIG. 2, 426 or 428 of FIG. 4, and/or 536 or 538 of FIG. 5).

The cross section 600 shows a first memory patch 610 (e.g., 256 of FIG. 2, 412 of FIG. 4, and/or 516 of FIG. 5), a staircase region 620 (e.g., 286 of FIG. 2, 414 of FIG. 4, and/or 524 of FIG. 5), and a second memory patch 630 (e.g., 257 of FIG. 2, 416 of FIG. 4, and/or 518 of FIG. 5). The cross section 600 also shows a row a SWDs 622 associated with the WLs running through the patches 610 and 630.

The view of FIG. 6 shows respective sense amplifiers 612 positioned above a first half of the memory patches 610 and 630. For example, the sense amplifiers SA0 to SA511 are shown coupled to GDLB0L to GDLB511L and GDLT0L to GDLT511L respectively. The other GDLs in the patches 610 to 630 from GDLB512L to GDLB1023L and GDLT512L to GDLT1023L are also coupled to sense amplifiers, but those sense amplifiers are in a different cross section not captured by the view of FIG. 6. The view of FIG. 6 shows a row of sense amplifiers, where adjacent sense amplifiers are coupled to adjacent GDLs. In other words, both even and odd GDLs couple to sense amplifiers which are in a same region.

Each word line is coupled to a respective SWD 622. For example the cross section 600 shows SWD0 to SWD99, which are associated with WL0 to WL99 respectively. The SWDs 622 are located above in the z direction a staircase region 620 which is between the two patches 610 and 630 in the x direction. Each SWD 622 is coupled to a vertical conductive element 624 which extends in the z direction to the associated word line. Along a row of SWDs 622 like the one shown in FIG. 6, each of these vertical conductive elements 624 may be a different length, since the WLs are at different depths in the z direction. In the example layout of FIG. 6, the shortest vertical conductive element, coupled to the ‘top’ word line WL0, is on the far left, while the longest vertical conductive element, coupled to the ‘bottom’ word line WL99, is on the far right. Other arrangements may be used in other example embodiments.

The cross section 600 shows a ‘stack’ of word lines. In this case the word lines WL0 to WL99. A number of LDLs extend vertically in the z direction and memory cells 502 are coupled at the intersection of the LDLs and the WLs. In the example implementation, there are 81,920 LDLs per patch from LDL0 to LDL81919. Each LDL seen in the cross section 600 represents a ‘top’ of a stack of 80 LDLs which extend in the y direction. Thus the leftmost LDL in the patch 610 is LDL0L, the next LDL is LDL80L, the next is LDL160L and so forth up to LDL81840L. Similarly, the LDLs in the patch 620 are LDL0R up to LDL81919R.

The view of FIG. 6 includes digit line multiplexers 644 (e.g., 184 of FIG. 1) in a digit line multiplexer region 640, and example multiplexer drivers 642. The multiplexers 644 selectively couple a set of LDLs to the respective GDLs. In the xz slice shown in FIG. 6, the multiplexers 644 of the left patch 610 are coupled to a multiplexer driver 642 and the multiplexers 644 of the right patch 630 are coupled to a multiplexer driver 643. The multiplexer drivers 642/643 are coupled along signal lines which extend in the x direction the multiplexer circuits 644. For example a first signal line couples the multiplexers 644 in the patch 610 to the driver 642 and a second signal line couples the multiplexers 644 in the patch 630 to the driver 643. The multiplexer drivers 642/643 and signal line represent a single row. Additional rows are stacked in the y direction in and out of the plane of the page.

Responsive to a row activation command and a row address, the SWD 622 specified by the row address activates the coupled word line along the respective vertical conductive element 624. This couples the memory cells 602 in the two patches 610 and 630 to be coupled to the LDLs which intersect that word line. Responsive to a signal from a global row decoder (e.g., 166 of FIG. 1) based on the row address, the multiplexer drivers 642 activate the multiplexers 644 to couple the LDLs along the cross section 600 to their respective GDLs. The memory cells along the activated WL drive a voltage onto the intersecting LDLs, which then drive a voltage to the coupled GDL through the activated multiplexers 644. The other LDLs, which are stacked in the Y direction and not visible in FIG. 6, are coupled to multiplexers which are coupled to different multiplexer drivers, and thus are not coupled to the GDLs. This may help reduce the capacitance of the GDL since each GDL is only coupled to one LDL at a time.

In some embodiments, the SWDs 622 and multiplexer drivers 642 may be located in a CMOS die (e.g., 212 of FIG. 2B) while the memory cells, LDLs, WLs, and, if used multiplexer region 640 are located in an array die (e.g., 216 of FIG. 2B). The vertical elements 624, as well as the vertical portions of the GDLs may extend from the array die to the CMOS die and may include contacts between the two dice not shown in FIG. 6.

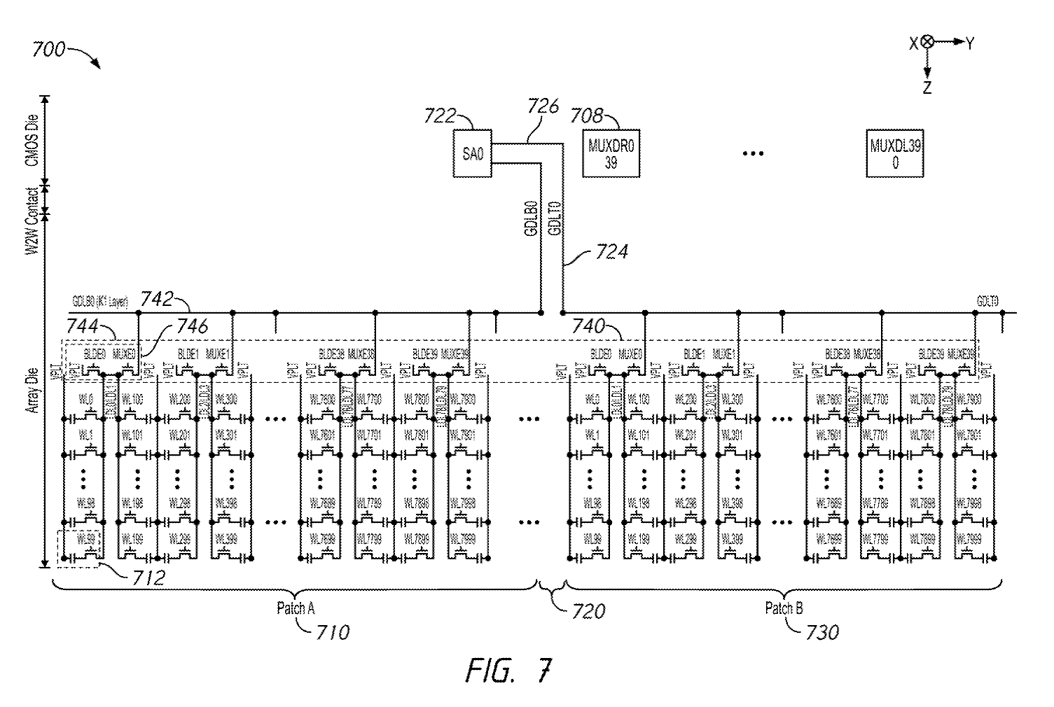

FIG. 7 is a cross sectional view of a memory device according to some embodiments of the present disclosure. The cross section 700 shows the plane 700 of FIG. 7. The cross section 700 represents a view along an example yz plane, showing two global digit lines running horizontally in the y direction, local digit lines running vertically in the z direction, and word lines running through the plane of the page in the x direction. The cross section 700 shows a first memory patch 710 (e.g., 256 of FIG. 2, 412 of FIG. 4, 516 of FIG. 5, and/or 610 of FIG. 6), an interpatch region 720 (e.g., 410 of FIG. 4 and/or 552 of FIG. 5), and a second memory patch 730 (e.g., 252 of FIG. 2, 402 of FIG. 4, and/or 512 of FIG. 5).

The cross section 700 intersects 8000 word lines in each memory patch 710 and 730. The word lines are organized in a grid in the yz plane with eighty columns in the z direction that have 100 word lines each. Accordingly, the cross section shows 16,000 memory cells 712, 8000 in each patch 710 and 730, with each patch organized in a grid of 80 memory cells in the x direction and 100 memory cells in the z direction. Each column of memory cells 712 is coupled to a local digit line, here labelled LDL0 to LDL79. In the embodiment of FIG. 7, the LDLs are paired and each pair LDLs is coupled in common to a multiplexer circuit 746. In some embodiments, each LDL may couple separately through a multiplexer to the GDL, rather than being paired.

Each memory cell 712 includes a capacitive element and a transistor. The gate of the transistor is coupled to the word line. One side of the capacitive element is coupled to a plate voltage VPLT, and the other side is coupled through the transistor to the LDL. When the word line is activated, the SWD drives a voltage along the word line which activates the transistor, coupling the capacitive element to the LDL.

The cross section 700 shows a sense amplifier 722. The sense amplifier 722 is labelled as SA0 because it is coupled to GDL0 in two adjacent patches 710 and 730. To distinguish them, those GDLs are labelled as GDLB0 in the first patch 710 and GDLT0 in the second patch 730. During an example operation, one of the two GDLs is used to carry information, and the other is used as a reference. For example, if a word line is activated in the first patch 710, then information is carried along GDLB0 and GDLT0 is used as a reference. During a read operation, the sense amplifier senses a difference between the GDL with information and the reference and then amplifies that difference. During a write operation, the sense amplifier drives one GDL to a voltage representing the write value and the other to the compliment of the write value.

The sense amplifier 722 is shown positioned above the memory patch 710. Vertical conductive elements 724 in the interpatch region 720 couple the GLDs GDLB0 and GDLT0 up from the array die to the CMOS die. Horizontal conductive elements 726 couple the vertical conductive elements from the interpatch region 720 to the location of the sense amplifier 722 over the array patch 710.

FIG. 7 shows multiplexer region 740 along with the multiplexer drivers 708 which operates the multiplexer region. The multiplexer circuits 746 are implemented by a multiplexer transistor 742 and an optional bleed transistor 744. Each pair of LDLs is coupled to the GDL through a multiplexer transistor 742. The gate of the multiplexer transistor 742 is coupled to a multiplexer control signal MUXE which is coupled to respective multiplexer drivers 708 along a signal line which runs in the x direction. The bleed transistor 744 selectively couples each pair of LDL to the plate voltage VPLT. The bleed transistors 744 have gates coupled to bleed control signals BLDE which are coupled to respective multiplexer drivers 708 along signal lines which run in the x direction. The multiplexer drivers 708 are controlled by global row decoders (e.g., 166 of FIG. 1).

During an example operation, if a row address is received associated with the first patch 710, then the multiplexer driver 708 which controls the LDL which intersects the WL activates the multiplexer transistor 742 by providing MUXE, and each of the other multiplexer drivers 708 provide BLDE to their respective bleed transistor 744 to couple those LDLs to VPLT and prevent them from floating. For example, if the row address indicates WL 101, which intersects LDL1, then MUXD0 provides MUXE0, which couples both LDL0 and LDL1 to GDLB0. The multiplexer drivers MUX1 to MUX4 provide BLDE1 to BLDE4 respectively, which couple the other LDLs LDL2 to LDL9 to VPLT through the respective bleed transistors 744.

In some embodiments, multiplexers may be activated on both sides of the sense amplifier in order to match capacitance between the signal and reference GDLs. Using the example above, a row address is received which indicates WL101 in patch 710. Accordingly, the signal will be along GDLB0 and the reference will be GDLT0. The multiplexer drivers MUXDL0 and MUXDR0 provide the signals MUXE0 to both patches 710 and 730. This causes the LDLs LDL0 and LDL1 in both patches 710 and 730 to be coupled to GDLB0 and GDLT0 respectively. The multiplexer driver MUXDL0 and MUXDR0 provide BLDE0 at an inactive level. The other multiplexer drivers MUXDL1 to MUXDL39 and MUXDR1 to MUXDR39 provide MUXE1 to MUXE39 at an inactive level and BLDE1 to BLDE39 at an active level.

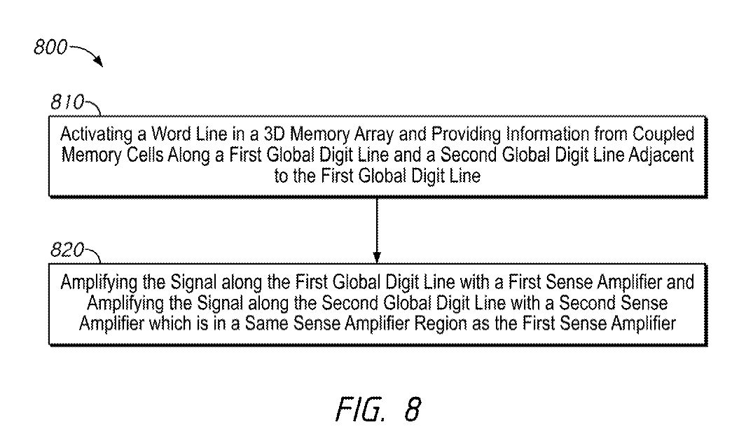

FIG. 8 is a flow chart of a method of operating a 3D memory array according to some embodiments of the present disclosure. The method 800 may, in some embodiments, be implemented by one or more of the apparatuses and/or systems described herein. For example, the method 800 may be implemented by the 3D memory device 100 of FIG. 1, 200 of FIG. 2, 300 of FIG. 3, the memory quilt 400 of FIG. 4, the views 500 of FIG. 5, 600 of FIG. 6, 700 of FIG. 7, or combinations thereof.

The method 800 may generally begin with box 810, which describes activating a word line in a 3D memory array and providing information from coupled memory cells along a first global digit line and a second global digit line adjacent to the first global digit line. For example, the method 800 may include receiving a row address as part of an access operation. A row decoder (e.g., 162 of FIG. 1) selects a SWD (e.g., 172 of FIG. 1, 520 of FIG. 5, and/or 622 of FIG. 6) in a SWD region (e.g., 272/276 of FIG. 2, 306 of FIG. 3, 404-414 of FIG. 4, 522/524 of FIG. 5, and/or 620 of FIG. 6). The method 800 includes activating the word line with the selected SWD through a staircase region. The activating word line extends in a first direction (e.g., an x direction) and intersects memory cells (e.g., 302 of FIG. 3, 602 of FIG. 6, and/or 712 of FIG. 7) at a plurality of local digit lines extending in a second direction (e.g., a z direction). The memory cells drive a signal as a voltage onto the associated local digit lines. The local digit lines couple the signal onto the respective global digit lines. The global digit lines extend in a third direction (e.g., a y direction). For example, the method 800 may include providing a first signal from a first memory cell along a first local digit line to the first global digit line and providing a second signal from a second memory cell along a second local digit line to the second global digit line.

In some embodiments, the method may include selecting a multiplexer driver (e.g., 176 of FIG. 1, 540 of FIG. 5, 642/643 of FIG. 6, and/or 708 of FIG. 7) in a multiplexer driver region (e.g., 242-248 of FIG. 2, 314-316 of FIG. 3, 452-458, and/or 542-548 of FIG. 5) based on the row address. The method may include selectively coupling the local digit lines which intersect the word line to the respective global digit lines through multiplexer circuits (e.g., 184 of FIG. 1, 318 of FIG. 3, 510 of FIG. 5, 644 of FIG. 6, and/or 746 of FIG. 7) activated by the selected multiplexer driver.

Box 810 may generally be followed by box 820 which describes amplifying the signal along the first global digit line with a first sense amplifier and amplifying the signal along the second global digit line with a second sense amplifier which is in a same sense amplifier region as the first sense amplifier. For example, the two sense amplifiers may be adjacent to each other in a same region.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a first 3D memory patch including a first plurality of memory cells disposed at the intersection of a first plurality of word lines extending in a first direction and a first plurality of local digit lines extending in a second direction orthogonal to the first direction, and a first plurality of global digit lines extending in a third direction orthogonal to the first and the second directions, the first plurality of global digit lines each coupled to a respective set of the first plurality of the local digit lines;
a second 3D memory patch including a second plurality of memory cells disposed at the intersection of a second plurality of word lines extending in the first direction and a second plurality of local digit lines extending in the second direction, and a second plurality of global digit lines extending in the third direction, the second plurality of global digit lines each coupled to a respective set of the second plurality of the local digit lines; and
a plurality of sense amplifiers, each coupled to one of the first plurality of global digit lines and to one of the second plurality of global digit lines, wherein adjacent ones of the plurality of sense amplifiers are coupled to adjacent ones of the first and the second plurality of global digit lines.

2. The apparatus of claim 1, further comprising an interpatch region disposed between the first 3D memory patch and the second 3D memory patch, wherein the plurality of sense amplifiers are coupled to the respective ones of the first and the second plurality of global digit lines by conductive elements extending in the second direction in the interpatch region.

3. The apparatus of claim 1, wherein a first portion of the plurality of sense amplifiers are coupled to a first half of the first and the second plurality of the global digit lines, and wherein a second portion of the plurality of global digit lines are coupled to a second half of the fist and the second plurality of the global digit lines.

4. The apparatus of claim 3, wherein the first portion of the plurality of sense amplifiers is located over first 3D memory patch in the second direction, and the second portion of the plurality of sense amplifiers is located over the second 3D memory patch in the second direction.

5. The apparatus of claim 1, further comprising:
a third 3D memory patch including a third plurality of memory cells disposed at the intersection of the first plurality of word lines and a third plurality of local digit lines extending in the second direction, and a third plurality of global digit lines extending in the third direction, the third plurality of global digit lines each coupled to a respective set of the third plurality of the local digit lines;
a fourth 3D memory patch including a fourth plurality of memory cells disposed at the intersection of the second plurality of word lines and a fourth plurality of local digit lines extending in the second direction, and a fourth plurality of global digit lines extending in the third direction, the fourth plurality of global digit lines each coupled to a respective set of the fourth plurality of the local digit lines; and
a second plurality of sense amplifiers, each coupled to one of the first plurality of global digit lines and to one of the second plurality of global digit lines, wherein adjacent ones of the second plurality of sense amplifiers are coupled to adjacent ones of the third and the fourth plurality of global digit lines.

6. The apparatus of claim 5, further comprising:
a first sub-word line driver region positioned between the first 3D memory patch and the third 3D memory patch, wherein the first sub-word line driver region comprises a first plurality of sub-word line drivers each coupled to one of the first plurality of word lines; and
a second sub-word line driver region positioned between the second 3D memory patch and the fourth 3D memory patch, wherein the second sub-word line driver region comprises a second plurality of sub-word line drivers each coupled to one of the second plurality of word lines.

7. The apparatus of claim 1, further comprising:
a first plurality of multiplexer drivers, each configured to selectively couple one of the respective set of the first plurality of local digit lines to the associated one of the first plurality of global digit lines; and
a second plurality of multiplexer drivers, each configured to selective couple one of the respective set of the second plurality of local digit lines to the associated one of the second plurality of global digit lines.

8. The apparatus of claim 1, wherein the first plurality of multiplexer drivers are located above the first 3D memory patch in the second direction, and wherein the second plurality of multiplexer drivers ae located above the second 3D memory patch in the second direction.

9. An apparatus comprising:
a first 3D memory patch including a plurality of first memory cells arranged in a3D array in X, Y and Z directions, the plurality of first memory cells divided into a plurality of first sets of memory cells and each of the first sets of memory cells is coupled to an associated one of a plurality of first global digit lines;
a second 3D memory patch including a plurality of second memory cells arranged in a3D array in the X, Y and Z directions, the plurality of second memory cells divided into a plurality of second sets of memory cells and each of the plurality of second sets of memory cells is coupled to an associated one of a plurality of second global digit lines;
a plurality of first sense amplifiers arranged, at least in part, above the first 3D memory patch, wherein the plurality of first sense amplifiers are coupled to ones of the plurality of first global digit lines and ones of the plurality of second global digit lines, respectively; and
a plurality of second sense amplifiers arranged, at least in part, above the second 3D memory patch, wherein the plurality of second sense amplifiers are coupled to remaining ones of the plurality of first global digit lines and remaining ones of the plurality of second global digit lines, respectively.

10. The apparatus of claim 9, wherein the plurality of first sense amplifiers do not overlap the second memory patch and the plurality of second sense amplifiers do not overlap the first memory patch.

11. The apparatus of claim 9, wherein the first 3D memory patch and the second 3D memory patch are arranged in the Y direction relative to each other, the apparatus further comprising:
a plurality of first sub-word line drivers provided, at least in part, above a first 3D region adjacent to the first 3D memory patch in the X direction, the plurality of first sub-word line drivers configured to drive a plurality of first word lines each coupled to a respective row of the plurality of first memory cells; and
a plurality of second sub-word line drivers provided, at least in part, above a second 3D region adjacent to the second 3D memory patch in the X direction, the plurality of second sub-word line drivers configured to drive a plurality of second word line each coupled to a respective row of the plurality of second memory cells.

12. The apparatus of claim 11, wherein the first 3D region includes a plurality of first vertical conductive elements each coupling an associated one of the plurality of first sub-word line drivers and an associated one of the plurality of first word lines and the second 3D structure patch includes a plurality of second vertical conductive elements each coupling an associated one of the plurality of second sub-word line drivers and an associated one of the plurality of second word lines.

13. The apparatus of claim 11, further comprising:
a plurality of first row decoders arranged, at least in part, above the first 3D memory patch, the plurality of first row decoders configured to provide first decode signals to the plurality of first sub-word line drivers, respectively; and
a plurality of second row decoders arranged, at least in part, above the second 3D memory patch, the plurality of second row decoders configured to provide second decode signals to the plurality of second sub-word line drivers, respectively.

14. The apparatus of claim 9, further comprising:
a third 3D memory patch including a plurality of third memory cells arranged in a 3D array in the X, Y and Z directions, the plurality of third memory cells divided into a plurality of third sets of memory cells and each of the third sets of memory cells is coupled to an associated one of a plurality of third global digit lines;
a fourth 3D memory patch including a plurality of fourth memory cells arranged in a 3D array in the X, Y and Z directions, the plurality of fourth memory cells divided into a plurality of fourth sets of memory cells and each of the fourth sets of memory cells is coupled to an associated one of a plurality of fourth global digit lines;
a plurality of third sense amplifiers arranged, at least in part, above the third 3D memory patch, wherein the plurality of third sense amplifiers are coupled to ones of the plurality of third global digit lines and ones of the plurality of fourth global digit lines, respectively; and
a plurality of fourth sense amplifiers arranged, at least in part, above the fourth 3D memory patch, wherein the plurality of fourth sense amplifiers are coupled to remaining ones of the plurality of third global digit lines and remaining ones of the plurality of fourth global digit lines, respectively.

15. The apparatus of claim 13, further comprising: a first plurality of word lines extending from the first 3D memory patch to the third 3D memory patch;
a second plurality of word lines extending from the second 3D memory patch to the fourth 3D memory patch, wherein the first and the second plurality of word lines extend in the X direction.

16. The apparatus of claim 9, further comprising:
a first plurality of multiplexer drivers coupled to a first plurality of multiplexers in the first 3D memory patch, the first plurality of multiplexer drivers positioned above the first 3D memory patch; and
a second plurality of multiplexer drivers coupled to a second plurality of multiplexers in the second 3D memory patch, the second plurality of multiplexer drivers positioned above the second 3D memory patch.

17. The apparatus of claim 9, wherein the first and the second 3D memory patches are located in a first die, and wherein the plurality of first sense amplifiers and the plurality of second sense amplifiers are located in a second die which is stacked above the first die in the Z direction.

18. The apparatus of claim 9, wherein within the plurality of first sense amplifiers and the plurality of second sense amplifiers adjacent sense amplifiers are coupled to adjacent ones of the plurality of first global digit lines and adjacent ones of the plurality of second global digit lines.

19. The apparatus of claim 9, wherein the plurality of first sense amplifiers and the plurality of second sense amplifiers each include sense amplifiers coupled to even global digit lines and sense amplifiers coupled to add global digit lines.

20. The apparatus of claim 9, wherein each of the first and the second 3D memory patches includes:
a plurality of word lines extending in the X direction; and
a plurality of local digit lines extending in the Z direction;
wherein the plurality of first global digit lines and the plurality of second global digit lines extend in the Y direction.

21. An apparatus comprising:
a word line extending in a first direction and coupled to a first memory cell and a second memory cell;
a first local digit line extending a second direction orthogonal to the first direction, the first local digit line coupled to the first memory cell;
a second local digit line extending in the second direction, the second local digit line coupled to the second memory cell;
a first global digit line extending a third direction orthogonal to the first and the second direction, the first global digit line coupled to the first local digit line;
a second global digit line extending in the third direction, the second global digit line coupled to the second local digit line, wherein the first and the second global digit lines are adjacent to each other;
a first sense amplifier coupled to the first global digit line; and
a second sense amplifier coupled to the second global digit line, wherein the first sense amplifier and the second sense amplifier are adjacent to each other and are positioned above the global digit lines in the second direction.

22. The apparatus of claim 21, further comprising an interpatch region, wherein the first sense amplifier and the second sense amplifier are coupled to the respective first and the second global digit lines by respective conductive elements running in the second direction in the interpatch region.

23. The apparatus of claim 21, wherein the first global digit line is an even global digit line and the second global digit line is an odd global digit line.

24. The apparatus of claim 21, further comprising:
a first multiplexer configured to selectively couple the first local digit line to the first global digit line; and
a second multiplexer configured to selectively couple the second local digit line to the second global digit line.

25. The apparatus of claim 24, further comprising a multiplexer driver coupled to the first multiplexer and the second multiplexer, wherein the multiplexer driver is positioned above the word line in the second direction.
